(19) United States
(12) Patent Application Publication
(10) Pub. No.: US 2021/0328577 A1
(43) Pub. Date: Oct. 21, 2021

(54) AUDIO RATE CONVERSION SYSTEM AND ELECTRONIC APPARATUS

(71) Applicant: Radiawave Technologies Co., Ltd., Shenzhen (CN)

(72) Inventors: Liuan ZHANG, Shenzhen (CN); Jon Sweat DUSTER, Beaverton, OR (US); Erkan ALPMAN, Portland, OR (US); Yulin TAN, Shenzhen (CN); Ning ZHANG, Shenzhen (CN); Haigang FENG, Shenzhen (CN)

(21) Appl. No.: 17/359,523

(22) Filed: Jun. 26, 2021

Related U.S. Application Data
(63) Continuation of application No. PCT/CN2020/080114, filed on Mar. 19, 2020.

(30) Foreign Application Priority Data
Mar. 19, 2019 (CN) 201910210344.8

(51) Int. Cl. H03H 17/02; G10L 19/24; H03H 17/06

(52) U.S. Cl. CPC H03H 17/0286; H03H 17/0671; G10L 19/24

(57) ABSTRACT

Disclosed are an audio rate conversion system and an electronic apparatus. The audio rate conversion system includes an integrator-comb filter, a multi-rate filter and a first half-band filter, an input of the integrator-comb filter being accessed with digital audio data, an output of the integrator-comb filter being sequentially connected to the multi-rate filter and the first half-band filter; where, the integrator-comb filter is configured to reduce a rate of the digital audio data according to a preset decimation rate; the multi-rate filter is configured to convert a rate of digital audio data output by the integrator-comb filter into a rate of digital audio data corresponding to an accessed control signal according to the control signal; and the first half-band filter is configured to reduce a rate of digital audio data output by the multi-rate filter.

### CROSS REFERENCE TO RELATED APPLICATIONS

This application is a Continuation Application of International Application No. PCT/CN2020/080114, filed on Mar. 19, 2020, which claims priority to Chinese Patent Application No. 201910210344.8, filed on Mar. 19, 2019 and entitled “Audio Rate Conversion System and Electronic Apparatus”. The disclosures of the aforementioned applications are hereby incorporated by reference in their entireties.

### TECHNICAL FIELD

This application relates to the technical field of integrated electronic circuits, in particular to an audio rate conversion system and an electronic apparatus.

### BACKGROUND

At present, in order to realize audio data conversion at various rates, it is generally necessary to replace different crystal oscillators to realize different audio rates. For example, a 24.576M Hz crystal oscillator is used to achieve 12 k, 24 k, 48 k, 96 k, 192 k audio rates; and a 11.2896M Hz crystal oscillator is used to achieve 11.025 k, 22.05 k, 44.1 k, 88.2 k, 176.4 k audio rates. Alternatively, when a fixed crystal oscillator is used, different audio rates are achieved by adding one or more phase-locked loops, however, the phase-locked loops can cause performance losses such as jitter.

### SUMMARY

The main object of this application is to provide an audio rate conversion system and an electronic apparatus, which aims to improve the versatility of the audio rate conversion system and avoid performance losses such as jitter caused by using phase-locked loops.

In order to achieve the above object, this application provides an audio rate conversion system, including an integrator-comb filter, a multi-rate filter and a first half-band filter, an input of the integrator-comb filter being accessed with digital audio data, an output of the integrator-comb filter being sequentially connected to the multi-rate filter and the first half-band filter; where,

the integrator-comb filter is configured to reduce a rate of the digital audio data according to a preset decimation rate;

the multi-rate filter is configured to convert a rate of digital audio data output by the integrator-comb filter into a rate of digital audio data corresponding to an accessed control signal according to the control signal; and

the first half-band filter is configured to reduce a rate of digital audio data output by the multi-rate filter.

Optionally, the preset decimation rate of the integrator-comb filter is 8/16/32/64/128/256, and the integrator-comb filter is configured to reduce a rate of digital audio data with a clock frequency of 12M Hz to 1500000/750000/375000/187500/93750/46875 Hz in sequence corresponding to the preset decimation rate;

or, the integrator-comb filter is configured to reduce a rate of digital audio data with a clock frequency of 8M Hz to 1000000/500000/250000/125000/62500/31250 Hz in sequence corresponding to the preset decimation rate.

Optionally, the multi-rate filter includes a first multi-rate filter supporting 48 k/96 k/192 k/384 k/768 k/1536 k Hz rate conversion, a second multi-rate filter supporting 32 k/64 k/128 k/256 k/512 k/1024 k Hz rate conversion and a third multi-rate filter supporting 44.1 k/88.2 k/176.4 k/352.8 k/705.6 k/1411.2 k Hz rate conversion, inputs of the first multi-rate filter, the second multi-rate filter and the third multi-rate filter are respectively connected to the integrator-comb filter, and outputs of the first multi-rate filter, the second multi-rate filter and the third multi-rate filter are respectively connected to the first half-band filter.

Optionally, the first multi-rate filter is configured to process digital audio data with a rate of 46875/93750/187500/375000/750000/1500000 Hz output by the integrator-comb filter to audio data with a rate of 48 k/96 k/192 k/384 k/768 k/1536 k Hz by sequentially multiplying 8, dividing 5, multiplying 8, dividing 5, multiplying 2 and dividing 5.

Optionally, the second multi-rate filter is configured to process digital audio data with a rate of 31250/62500/125000/250000/500000/1000000 Hz output by the integrator-comb filter to audio data with a rate of 32 k/64 k/128 k/256 k/512 k/1024 k Hz by sequentially multiplying 8, dividing 5, multiplying 8, dividing 5, multiplying 2 and dividing 5.

Optionally, the third multi-rate filter is configured to process digital audio data with a rate of 46875/93750/187500/375000/750000/1500000 Hz output by the integrator-comb filter to audio data with a rate of 44.1 k/88.2 k/176.4 k/352.8 k/705.6 k/1411.2 k Hz by sequentially multiplying 16 and dividing 17.

Optionally, the first half-band filter is one of two first half-band filters, and the two first half-band filters are sequentially connected to an output of the multi-rate filter.

Optionally, the audio rate conversion system further includes a second half-band filter arranged in series between the integrator-comb filter and the multi-rate filter.

Optionally, the audio rate conversion system further includes an analog digital converter, where an output of the analog digital converter is connected to the input of the integrator-comb filter, and the analog digital converter is configured to convert received analog audio data into the digital audio data and then output the digital audio data to the integrator-comb filter.

This application further provides an electronic apparatus including the audio rate conversion system as described above. The audio rate conversion system includes an integrator-comb filter, a multi-rate filter and a first half-band filter, an input of the integrator-comb filter being accessed with digital audio data, an output of the integrator-comb filter being sequentially connected to the multi-rate filter and the first half-band filter; where, the integrator-comb filter is configured to reduce a rate of the digital audio data according to a preset decimation rate; the multi-rate filter is configured to convert a rate of digital audio data output by the integrator-comb filter into a rate of digital audio data corresponding to an accessed control signal according to the control signal; and the first half-band filter is configured to reduce a rate of digital audio data output by the multi-rate filter.

According to the audio rate conversion system of this application, an integrator-comb filter is provided to reduce a rate of digital audio data according to a preset decimation rate and then output the digital audio data to a multi-rate filter, the multi-rate filter is configured to convert a rate of the digital audio data output by the integrator-comb filter into a rate of digital audio data corresponding to an accessed control signal and then output the digital audio data to a first half-band filter, so that the first half-band filter reduces a rate of digital audio data output by the multi-rate filter. The integrator-comb filter of this application is mainly composed of an integrator, an adder, and a register, it does not need a multiplier and has no coefficient-free memory, so it occupies less logical resources. The half-band filter and the multi-phase filter in the multi-rate filter can realize audio demands at various rates, so that this application can realize various rate conversion of audio data without replacing the crystal oscillator. This application can further use different filter orders according to requirements, so as to ensure good rate conversion performance in both low and high frequency bands of audio. This application does not need to use phase-locked loops, so that it can avoid performance losses such as jitter caused by the phase-locked loops to the crystal oscillators, and improve the versatility of the audio rate conversion system.

### BRIEF DESCRIPTION OF THE DRAWINGS

In order to more clearly explain the embodiments of this application or the technical solutions in the prior art, the drawings used in the description of the embodiments or the prior art will be briefly introduced below. Obviously, the drawings in the following description are merely some embodiments of this application. For those of ordinary skill in the art, other drawings can be obtained based on the structure shown in these drawings without paying creative work.

FIG. 1 is a schematic diagram of functional modules of an audio rate conversion system according to an embodiment of this application.

FIG. 2 is a schematic diagram of a circuit structure of a half-band filter in a multi-rate filter according to an embodiment of this application.

FIG. 3 is a schematic diagram of an implementation model of a first multi-phase filter in the multi-rate filter of this application.

FIG. 4 is a schematic diagram of the circuit structure of the half-band filter in the multi-rate filter according to another embodiment of this application.

FIG. 5 is a schematic diagram of an implementation model of a second multi-phase filter in the multi-rate filter of this application.

FIG. 6 is a schematic flow diagram showing rate conversion of a first multi-rate filter in the multi-rate filter of this application.

FIG. 7 is a schematic flow diagram showing rate conversion of a third multi-rate filter in the multi-rate filter of this application.

FIG. 8 is a frequency response curve of an integrator-comb filter.

FIG. 9 is a frequency response curve of a half-band filter.

The realization of the object, functional characteristics, and advantages of this application will be further described in connection with the embodiments and with reference to the accompanying drawings.

### DETAILED DESCRIPTION OF THE EMBODIMENTS

In the following, the technical solutions in the embodiments of this application will be clearly and completely described in connection with the drawings in the embodiments of this application. Obviously, the described embodiments are only a part of the embodiments of this application, but not all of the embodiments. Based on the embodiments of this application, all other embodiments obtained by those of ordinary skill in the art without creative efforts shall fall within the claimed scope of this application.

It should be noted that all directional indicators (such as up, down, left, right, front, back, etc.) in the embodiments of this application are only used to explain the relative positional relationship, movement situation, etc. between components in a specific posture (as shown in the drawings). If the specific posture changes, the directional indication also changes accordingly.

In addition, the descriptions related to “first”, “second”, and the like in this application are for descriptive purposes only, and cannot be understood as indicating or implying their relative importance or implicitly indicating the number of technical features indicated. Therefore, features associated with “first” and “second” may explicitly or implicitly include at least one of such feature. In addition, the technical solutions of the various embodiments can be combined with each other, but they must be based on what can be achieved by those of ordinary skill in the art. When the combination of technical solutions is contradictory or cannot be achieved, it should be considered that such a combination of technical solutions does not exist, or is not within the scope of protection defined by the claims of this application.

This application provides an audio rate conversion system.

The audio rate conversion system of this application can convert rate of different audio data to 48 k/96 k/192 k/384 k/768 k/1536 k Hz, 32 k/64 k/128 k/256 k/512 k/1024 k Hz or 44.1 k/88.2 k/176.4 k/352.8 k/705.6 k/1411.2 k Hz. At present, in order to realize the above-mentioned audio data conversion, it is generally necessary to replace different crystal oscillators to realize different audio rates. For example, a 24.576M Hz crystal oscillator is configured to achieve 12 k/24 k/48 k/96 k/192 k Hz audio rates; and a 11.2896M Hz crystal oscillator is configured to achieve 11.025 k/22.05 k/44.1 k/88.2 k/176.4 k Hz audio rates. Alternatively, when a fixed crystal oscillator is used, different audio rates are achieved by adding one or more phase-locked loops. For example, some manufacturers use 24M Hz crystal oscillator combined with phase-locked loops 24 k/48 k/96 k/192 k Hz or 1.025 k/22.05 k/44.1 k/88.2 k/176.4 k Hz. In addition to the clock, there are usually rate conversions using farrow filters or sinc function filters. However, these filters will remove signal components above a given bandwidth and only retain low-frequency signal, so they will bring more performance losses, especially for the high-frequency band of audio data.

In order to solve the above problem, referring to FIG. 1, in an embodiment of this application, the audio rate conversion system includes an integrator-comb filter 10, a multi-rate filter 20 and a first half-band filter 30, an input of the integrator-comb filter 10 being accessed with digital audio data, an output of the integrator-comb filter 10 being sequentially connected to the multi-rate filter 20 and the first half-band filter 30; where,

the integrator-comb filter 10 is configured to reduce a rate of the digital audio data according to a preset decimation rate;

the multi-rate filter 20 is configured to convert a rate of digital audio data output by the integrator-comb filter 10 into a rate of digital audio data corresponding to an accessed control signal according to the control signal; and

the first half-band filter 30 is configured to reduce a rate of digital audio data output by the multi-rate filter 20.

In this embodiment, the integrator-comb filter 10, the multi-rate filter 20, and the half-band filter 30 are all integrated into the integrated chip. The audio rate conversion system may further be integrated with an analog digital converter 50, where an output of the analog digital converter 50 is connected to the input of the integrator-comb filter 10, and the analog digital converter 50 is configured to convert received analog audio data into the digital audio data and then output the digital audio data to the integrator-comb filter 10. Certainly, in other embodiments, the analog digital converter 50 can also be connected to the audio rate conversion system through an interface, independent of the audio rate conversion system.

In another embodiment, the audio rate conversion system can also be integrated with a Pulse Density Modulation (PDM) interface, that is, the input of the integrator-comb filter 10 can be accessed with digital audio data output by the PDM interface, so as to realize rate conversion. Or, the PDM interface can also be connected to the audio rate conversion system through an interface, independent of the audio rate conversion system.

The integrator-comb filter 10 can be cascaded from integrators and comb filters. Multiple integrators and comb filters can be provided, and the multiple integrators can be cascaded, similarly, the multiple comb filters can also be cascaded, and when the integrator group is cascaded by several integrators, the number of stages thereof is the same as that of the comb filter group. According to different positions of the integrators and combs, the functions of decimation and interpolation can be realized respectively. Optionally, this embodiment can be realized by a decimation-type integrator-comb filter 10 with the integrator in front and the comb in behind, to achieve down-conversion processing. The accessed digital audio data is downsampled through the integrator-comb filter 10, that is, the rate of data is reduced (mainly using Nyquist sampling theorem, ensuring non-aliasing) according to different decimation rates, the integrator-comb filter 10 can prevent the occurrence of spectrum aliasing with a filter while completing the reduction of the sampling rate. Specifically, the number of cascades required for the integrator-comb filter 10 can be determined based on the anti-aliasing index to reduce aliasing noise, while the integrator-comb filter 10 can also increase Effective Number of Bits (ENOB).

In other embodiments, a second half-band filter 40 may be further provided at a later stage of the integrator-comb filter 10 to further reduce the rate of data being accessed and to suppress high frequency noise. For example, for a data with a sampling rate of 12M Hz, the rate is reduced to 125000 Hz through the integrator-comb filter 10, and then further reduced to 62500 Hz through the half-band filter. It can be understood that after decimation by the integrator-comb filter 10, the data rate enters a first sub-lobe, and the more Half-Band Filters (HBFs) followed, the better the anti-aliasing performance. As shown in FIG. 9, FIG. 9 is a frequency response curve of the integrator-comb filter 10, the noise in the wide rectangle A can be aliased into the narrow rectangle B (there are similar wide rectangles in other sub-lobes, not shown). Certainly, the more HBFs, the lower the decimation rate of the integrator-comb filter 10, resulting in a small increase in ENOB. Therefore, when the oversampling rate of the analog digital converter 50 is not high, the second half-band filter 40 may be bypassed.

In this embodiment, the multi-rate filter 20 is integrated with multiple filter banks, so as to convert the digital audio data output by the integrator-comb filter 10 into one or more combinations of 48 k/96 k/192 k/384 k/768 k/1536 k Hz, 32 k/64 k/128 k/256 k/512 k/1024 k Hz or 44.1 k/88.2 k/176.4 k/352.8 k/705.6 k/1411.2 k Hz according to the accessed control signal. The control signal can be a rate mode selection signal, that is, when receiving an external input rate mode selection signal, a corresponding filter rate configuration value is selected in the register group, and the register group is pre-stored with filter rate configuration values corresponding to each rate mode selection signal. The rate of audio data received under the current rate mode selection signal is converted according to the filter rate configuration value. The control signal can be selection signal input from the external MCU to the audio rate conversion system, or selection signal output by the user through the upper computer programming configuration, which can be chosen by users according to their own needs, so as to convert the sampled digital audio data into one group of audio data of 48 k/96 k/192 k/384 k/768 k/1536 k Hz, 32 k/64 k/128 k/256 k/512 k/1024 k Hz or 44.1 k/88.2 k/176.4 k/352.8 k/705.6 k/1411.2 k Hz and then output. The multi-rate filter 20 can be implemented using an interpolation-type half-band filter and a multi-phase filter 22, and the numbers and connection relationship of the interpolation-type half-band filter and the multi-phase filter 22 can be set according to the corresponding audio data rate conversion requirements. The system can use a 48M Hz crystal oscillator to provide a clock signal.

The first half-band filter 30 can be combined with the integrated-comb filter 10 to enhance the anti-aliasing effect, and can also be configured to reduce the order of the multi-rate filter 20, thereby reducing resource consumption. This application can be applied to the Analog Digital Converter (ADC) 50 which is configured for conversion between analog and digital data to reduce rate and convert rate after oversampling. After ADC data is output for rate reduction by the integrator-comb filter 10, it can first pass through the HBF to perform a rate reduction by half, then pass through the multi-rate filter 20 to increase the rate 4 times, and then pass through the first half-band filter 30 to reduce the 4 times rate output by the multi-rate filter 20 to 2 times or 1 time rate. Referring to FIG. 9, FIG. 9 is a frequency response curve of the half-band filter. In this embodiment, the first half-band filter 30 and the second half-band filter 40 are both decimated-type half-band filters, and configured to achieve 2 times decimation. The half-band filter is a special low-pass FIR digital filter, which is symmetrical with respect to the ½ Nyquist frequency due to the passband and stopband.

According to this application, an integrator-comb filter 10 is provided to reduce a rate of digital audio data according to a preset decimation rate and then output the digital audio data to a multi-rate filter 20, the multi-rate filter 20 is configured to convert a rate of the digital audio data output by the integrator-comb filter 10 into a rate of digital audio data corresponding to an accessed control signal and then output the digital audio data to a first half-band filter 30, so that the first half-band filter 30 reduces a rate of digital audio data output by the multi-rate filter. The integrator-comb filter 10 of this application is mainly composed of an integrator, an adder, and a register, it does not need a multiplier and has no coefficient memory, so it occupies less logical resources. The half-band filter and the multi-phase filter 22 in the multi-rate filter 20 can realize the audio demand at various rates, so that this application can realize the multi-rate conversion of audio data without replacing the crystal oscillator. This application can also use different filter orders according to requirements, so as to ensure good rate conversion performance in both low and high frequency bands of audio. This application does not need to use phase-locked loops, so that it can avoid performance losses such as jitter caused by the phase-locked loops to the crystal oscillators. This application improves the versatility of the audio rate conversion system.

Referring to FIGS. 1 to 5, in an embodiment, the preset decimation rate of the integrator-comb filter 10 is 8/16/32/64/128/256, and as shown in Table 1, the integrator-comb filter 10 is configured to reduce a rate of digital audio data with a clock frequency of 12M Hz to 1500000/750000/375000/187500/93750/46875 Hz in sequence corresponding to the preset decimation rate;

or as shown in Table 2, the integrator-comb filter is configured to reduce a rate of digital audio data with a clock frequency of 8M Hz to 1000000/500000/250000/125000/62500/31250 Hz in sequence corresponding to the preset decimation rate.

In this embodiment, the integrator-comb filter 10 may set different decimation rates according to actual applications, and downsample audio data with different clock frequencies (sampling rates).

TABLE 1

| | | | | | | |
|---|---|---|---|---|---|---|
| Clock frequency | 120000000 | 12000000 | 12000000 | 12000000 | 12000000 | 12000000 |
| (Hz) | | | | | | |
| CIC decimation | 8 | 16 | 32 | 64 | 128 | 256 |
| rate | | | | | | |
| Conversion | 1500000 | 750000 | 375000 | 187500 | 93750 | 46875 |
| rate (Hz) | | | | | | |

TABLE 2

| | | | | | | |
|---|---|---|---|---|---|---|
| Clock | 8000000 | 8000000 | 8000000 | 8000000 | 8000000 | 8000000 |
| frequency | | | | | | |
| (Hz) | | | | | | |
| CIC | 8 | 16 | 32 | 64 | 128 | 256 |
| decimation | | | | | | |
| rate | | | | | | |
| Conversion | 1000000 | 500000 | 250000 | 125000 | 62500 | 31250 |
| rate (Hz) | | | | | | |

Referring to FIGS. 1 to 5, in an embodiment, the multi-rate filter 20 includes a first multi-rate filter 20 supporting 48 k/96 k/192 k/384 k/768 k/1536 k Hz rate conversion, a second multi-rate filter 20 supporting 32 k/64 k/128 k/256 k/512 k/1024 k Hz rate conversion and a third multi-rate filter 20 supporting 44.1 k/88.2 k/176.4 k/352.8 k/705.6 k/1411.2 k Hz rate conversion, inputs of the first multi-rate filter 20, the second multi-rate filter 20 and the third multi-rate filter 20 are respectively connected to the integrator-comb filter 10, and outputs of the first multi-rate filter 20, the second multi-rate filter 20 and the third multi-rate filter 20 are respectively connected to the first half-band filter 30.

In this embodiment, the first multi-rate filter 20, the second multi-rate filter 20 and the third multi-rate filter 20 can convert audio data of different rates, and composition of the half-band filters and multi-phase filters 22 of these three are also different corresponding to different rates of audio data.

Specifically, referring to FIG. 6, the first multi-rate filter 20 is configured to process digital audio data with a rate of 46875/93750/187500/375000/750000/1500000 Hz output by the integrator-comb filter 10 to audio data with a rate of 48 k/96 k/192 k/384 k/768 k/1536 k Hz by sequentially multiplying 8, dividing 5, multiplying 8, dividing 5, multiplying 2 and dividing 5.

In this embodiment, the output rate of the integrator-comb filter 10 being 46875 Hz is taken as an example, when 48000 Hz audio rate is needed, the rate conversion is required.

48000/46875=1.024=128/125, where the conversion factor is 1.024.

In order to obtain 48000 Hz audio rate, the 48000 Hz rate can multiply 128 and then divide 125. However, doing so will cause the clock to rise too high and the filter order to be too high. Therefore, the rate conversion can be decomposed. As shown in FIG. 6, the rate of audio data can multiply 8, divide 5, multiply 8, divide 5, multiply 2 and divide 5, so that decimal rate conversion can be completed. In this process, the clock of the analog digital converter 50 is configured as 12M Hz, 6M Hz or 3M Hz.

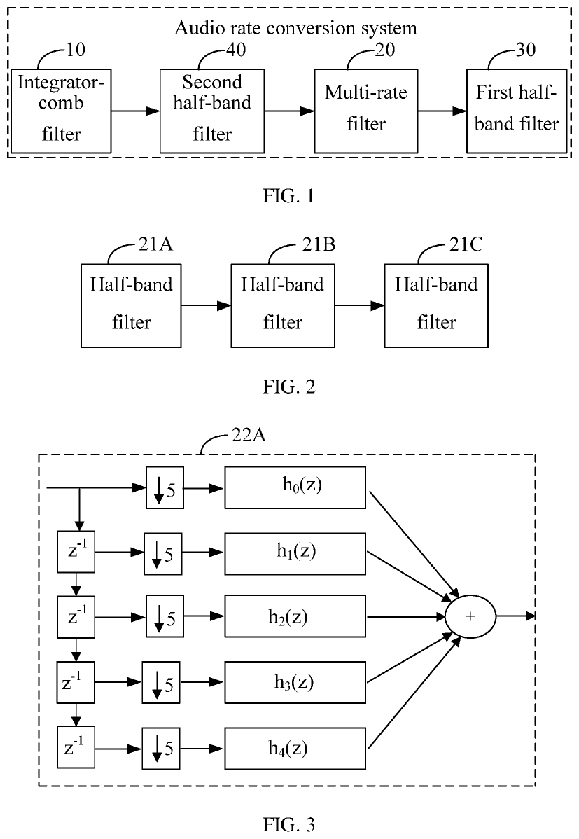

Referring to FIG. 2, multiplying 8 can be realized by using three half-band filters (21A˜21C), and the three half-band filters are all interpolation-type half-band filters to achieve 2× interpolation. After cascading the three half-band filters, the input audio data is raised. While dividing 5 can be realized by using the first multi-phase filter 22A with the operating frequency being 4 times the audio rate. The multi-phase filter 22 decomposes a system function h(z) of the digital filter into several groups with different phases according to the phase uniform division to form multiple branches, and filtering is realized on each branch. The implementation model of the first multi-phase filter 22A may refer to FIG. 3. The multi-phase filter 22 allows the filter to operate at a lower frequency without a phase-locked loop. The first multi-phase filter 22A model can be described by the formula as follows:

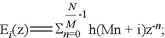

Where N is filter length and M is number of phases decomposed.

In conjunction with Table 3, Table 3 shows input or output of conversion rate of each filter when the second multi-rate filter 20 is built using a half-band filter and a multi-phase filter 22. Where Hbf_inck is rate of audio data accessed by the second half-band filter 40, Lm_18_hbf0_inck˜Lm_18_hbf2_incl is rate of audio data accessed by the three half-band filters in the multi-phase filter 22, Lm_m5_inclk is rate of audio data accessed by the multi-phase filter 22, and Hbf1_inclk˜Hbf2_inclk is rate of audio data accessed when two first half-band filters 30 are provided.

TABLE 3

| Clock rate | 12000000 | 12000000 | 12000000 | 12000000 | 12000000 |
|---|---|---|---|---|---|
| Decimation rate of | 128 | 64 | 32 | 16 | 8 |
| integrator-comb | | | | | |
| filter 10 | | | | | |
| CIC clkout (Hz) | 93750 | 187500 | 375000 | 750000 | 1500000 |
| Hbf0_inclk (Hz) | 93750 | 187500 | 375000 | 750000 | 1500000 |
| Lm_18_hbf0_inclk | 46875 | 93750 | 187500 | 375000 | 750000 |
| (Hz) | | | | | |
| Lm_18_hbf1_inclk | 93750 | 187500 | 375000 | 750000 | 1500000 |
| (Hz) | | | | | |
| Lm_18_hbf2_inclk | 187500 | 375000 | 750000 | 1500000 | 3000000 |
| (Hz) | | | | | |
| Lm_m5_inclk (Hz) | 37500 | 75000 | 150000 | 300000 | 600000 |
| Lm_18_hbf0_inclk | 75000 | 150000 | 300000 | 600000 | 1200000 |
| (Hz) | | | | | |
| Lm_18_hbf1_inclk | 150000 | 300000 | 600000 | 1200000 | 2400000 |
| (Hz) | | | | | |
| Lm_18_hbf2_inclk | 300000 | 600000 | 1200000 | 2400000 | 4800000 |
| (Hz) | | | | | |
| Lm_m5_inclk (Hz) | 60000 | 120000 | 240000 | 480000 | 960000 |
| Lm_12_hbf0_inclk | 120000 | 240000 | 480000 | 960000 | 1920000 |
| (Hz) | | | | | |
| Lm_m5_inclk (Hz) | 24000 | 48000 | 96000 | 192000 | 384000 |
| Hbf1_inclk (Hz) | 48000 | 96000 | 192000 | 384000 | 768000 |
| Hbf2_inclk (Hz) | 24000 | 48000 | 96000 | 192000 | 384000 |
| Output (Hz) | 12000 | 24000 | 48000 | 96000 | 192000 |

Referring to FIGS. 1 to 6, in an embodiment, the second multi-rate filter 20 is configured to process digital audio data with a rate of 31250/62500/125000/250000/500000/1000000 Hz output by the integrator-comb filter 10 to audio data with a rate of 32 k/64 k/128 k/256 k/512 k/1024 k Hz by sequentially multiplying 8, dividing 5, multiplying 8, dividing 5, multiplying 2 and dividing 5. In this process, the clock of the analog digital converter 50 is configured as 12M Hz, 6M Hz or 3M Hz.

In this embodiment, the output rate of the integrator-comb filter 10 being 31250 Hz is taken as an example, when 32000 Hz audio rate is needed, the rate conversion is required.

32000/31250=1.024=128/125, where the conversion factor is 1.024.

In order to obtain 32000 Hz audio rate, the rate also needs to multiply 128 and then divide 125. For specific reference to the 48000 Hz conversion. It can be understood that the first multi-rate filter 20 and the second multi-rate filter 20 can be two independent filters, or the two can be shared, no restrictions are made here. The clock of the analog digital converter 50 can be configured as 8M Hz, 4M Hz or 2M Hz.

In conjunction with Table 4, Table 4 shows the input or output of the conversion rate of each filter when the second multi-rate filter 20 is built using a half-band filter and a multi-phase filter 22.

Where CIC clkout(Hz) is rate of audio data output by the integrator-comb filter 10, Hbf0_inck is rate of audio data accessed by the second half-band filter 40, Lm_18hbf0_inck˜Lm_18_hbf2_incl is rate of audio data accessed by the three half-band filters in the multi-phase filter 22, Lm_m5_inck is rate of audio data accessed by the multi-phase filter 22, and Hbf1_inclk˜Hbf2 inclk is rate of audio data accessed when two first half-band filters 30 are provided.

TABLE 4

| Clock rate | 8000000 | 8000000 | 8000000 | 8000000 | 8000000 |
|---|---|---|---|---|---|
| Decimation rate | 128 | 64 | 32 | 16 | 8 |
| CIC clkout (Hz) | 62500 | 125000 | 250000 | 500000 | 1000000 |
| Hbf0_inclk (Hz) | 62500 | 125000 | 250000 | 500000 | 1000000 |
| Lm_18_hbf0_inclk | 31250 | 62500 | 125000 | 250000 | 500000 |
| (Hz) | | | | | |
| Lm_18_hbf1_inclk | 62500 | 125000 | 250000 | 500000 | 1000000 |
| (Hz) | | | | | |
| Lm_18_hbf2_inclk | 125000 | 250000 | 500000 | 1000000 | 2000000 |
| (Hz) | | | | | |
| Lm_m5_inclk (Hz) | 25000 | 50000 | 100000 | 200000 | 400000 |
| Lm_18_hbf0_inclk | 50000 | 100000 | 200000 | 400000 | 800000 |
| (Hz) | | | | | |
| Lm_18_hbf1_inclk | 100000 | 200000 | 400000 | 800000 | 1600000 |
| (Hz) | | | | | |
| Lm_18_hbf2_inclk | 200000 | 400000 | 800000 | 1600000 | 3200000 |
| (Hz) | | | | | |
| Lm_m5_inclk (Hz) | 40000 | 80000 | 160000 | 320000 | 640000 |
| Lm_12_hbf0_inclk | 80000 | 160000 | 320000 | 640000 | 1280000 |
| (Hz) | | | | | |
| Lm_m5_inclk (Hz) | 16000 | 32000 | 64000 | 128000 | 256000 |
| Hbf1_inclk (Hz) | 32000 | 64000 | 128000 | 256000 | 512000 |
| Hbf2_inclk (Hz) | 16000 | 32000 | 64000 | 128000 | 256000 |
| Output (Hz) | 8000 | 16000 | 32000 | 64000 | 128000 |

Referring to FIGS. 1 to 5, in an embodiment, the third multi-rate filter 20 is configured to process digital audio data with a rate of 46875/93750/187500/375000/750000/1500000 Hz output by the integrator-comb filter 10 to audio data with a rate of 44.1 k/88.2 k/176.4 k/352.8 k/705.6 k/1411.2 k Hz by sequentially multiplying 16 and dividing 17.

In this embodiment, the rate output by the integrator-comb filter 10 being 46875 Hz is taken as an example, when 44.117 k Hz audio rate needs to be obtained, the rate conversion is required. When 44.1 k/88.2 k/176.4 k/352.8 k/705.6 k/1411.2 k Hz is supported, the method of audio rate approximation can be adopted, for example, the 44.1 k Hz rate is replaced by 44.117 k Hz((12M Hz)/272).

(12M Hz)/272=44.117k Hz; (12M Hz)/256=46.875k Hz

(44.117k)/(46. 875k)=256/272=16/17

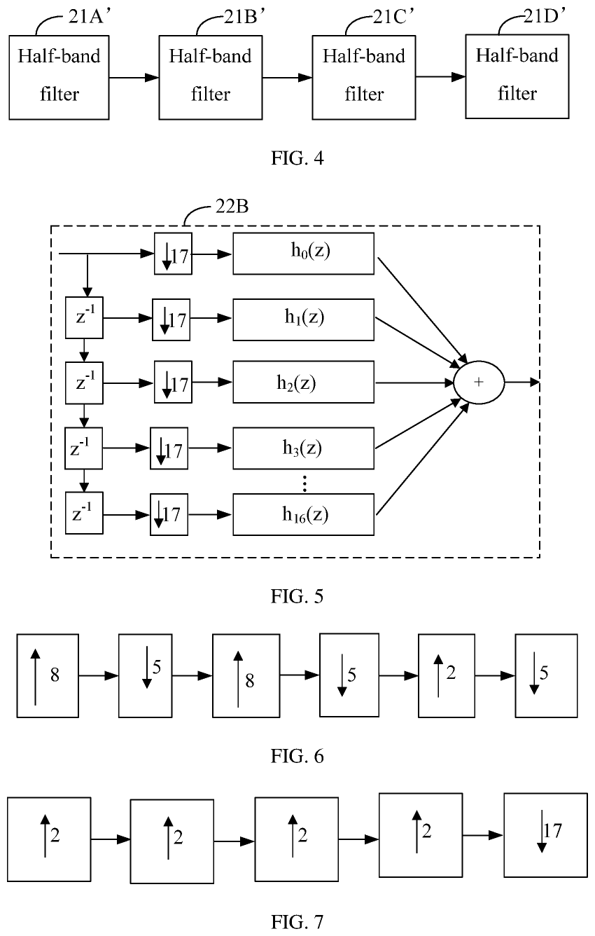

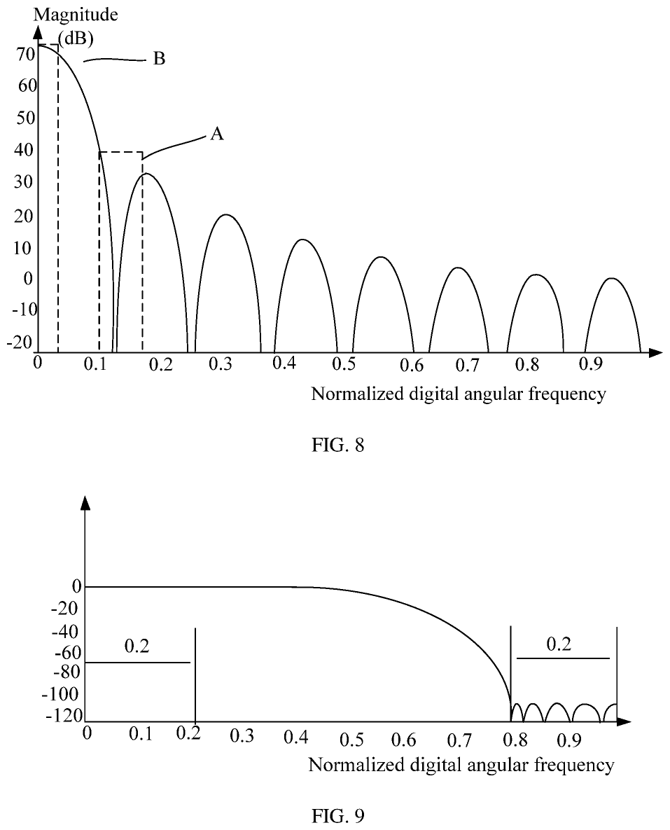

Referring to FIG. 4 and FIG. 7, multiplying 16 can be achieved by sampling four half-band filters (21A′˜21D′) to increase the rate to 16 times. While dividing 17 can be achieved by using a multi-phase filter 22 to reduce the rate to 1/17. The multi-phase filter 22 operates at a frequency of 4 times the audio rate. In order to reduce the number of filters in the system and reduce the cost, the four half-band filters can be shared with the half-band filters in the 1.024 decimal rate conversion. While dividing 17 can be achieved by using a second multi-phase filter 22B with the operating frequency being 4 times the audio rate. The multi-phase filter 22 decomposes the system function h(z) of the digital filter into several groups with different phases according to the phase uniform division to form multiple branches, and filtering is realized on each branch. The implementation model of the second multi-phase filter 22B may refer to FIG. 5. The multi-phase filter 22 allows the filter to operate at a lower frequency without a phase-locked loop. The first multi-phase filter 22B model can be described by the formula as follows:

$${E}_{i} ( z ) = {\sum }_{n = 0}^{\frac{N}{M} - 1} h ( M n + i ) {z}^{- n} ;$$

Where N is filter length and M is number of phases decomposed.

In conjunction with Table 5, Table 5 shows input or output of the conversion rate of each filter when the second multi-rate filter 20 is built using a half-band filter and a multi-phase filter 22.

Where CIC clkout(Hz) is rate of audio data output by the integrator-comb filter 10, Hbf0_inck is rate of audio data accessed by the second half-band filter 40, Lm_18_hbf0_inck˜Lm_18_hbf3_incl is rate of audio data accessed by the four half-band filters in the multi-phase filter 22, Lm_m17_inck is rate of audio data accessed by the multi-phase filter 22, and Hbf1_inclk˜Hbf2_inclk is rate of audio data accessed when two first half-band filters 30 are provided.

TABLE 5

| Clock rate (Hz) | 12000000 | 12000000 | 12000000 | 12000000 | 12000000 |
|---|---|---|---|---|---|
| Decimation rate | 128 | 64 | 32 | 16 | 8 |
| CIC clkout (Hz) | 93750 | 187500 | 375000 | 750000 | 1500000 |
| Hbf0_inclk (Hz) | 93750 | 187500 | 375000 | 750000 | 1500000 |
| Lm_116_hbf0_inclk | 46875 | 93750 | 187500 | 375000 | 750000 |
| (Hz) | | | | | |
| Lm_116_hbf1_inclk | 93750 | 187500 | 375000 | 750000 | 1500000 |
| (Hz) | | | | | |
| Lm_116_hbf2_inclk | 187500 | 375000 | 750000 | 1500000 | 3000000 |
| (Hz) | | | | | |
| Lm_116_hbf3_inclk | 375000 | 750000 | 1500000 | 3000000 | 6000000 |
| (Hz) | | | | | |
| Lm_m17_inclk (Hz) | 75000 | 150000 | 300000 | 600000 | 1200000 |
| Hbf1_inclk (Hz) | 44117.647 | 88235.294 | 176470.588 | 352941.176 | 705882.352 |
| Hbf2_inclk (Hz) | 22058.8235 | 44117.647 | 88235.294 | 176470.588 | 352941.176 |
| Output (Hz) | 11029.41175 | 22058.8235 | 44117.647 | 88235.294 | 176470.588 |

Referring to FIGS. 1 to 5, in another embodiment, the third multi-rate filter is configured to process digital audio data with a rate of 48 k/96 k/192 k/384 k/768 k/1536 k Hz output by the first multi-rate filter to audio data with a rate of 44.1 k/88.2 k/176.4 k/352.8 k/705.6 k/1411.2 k Hz by sequentially multiplying 7, dividing 8, multiplying 7, dividing 5, multiplying 3 and dividing 4.

In this embodiment, when 44.11 k (Hz) audio rate needs to be obtained, the 44.1 k (Hz) can be obtained from the 48 k Hz output by the first multi-rate filter.

44100/48000=147/160

In order to obtain 44100 Hz rate, the rate can multiply 147 and then divide 160. However, doing so will cause the clock to rise too high and the filter order to be too high. Therefore, the rate conversion can be decomposed. Specifically, the rate of audio data can multiply 7, divide 8, multiply 7, divide 5, multiply 3 and divide 4, so that the decimal rate conversion can be completed. In this process, the multi-rate filter is required to support 48 k/96 k/192 k/384 k/768 k/1536 k Hz and 44.1 k/88.2 k/176.4 k/352.8 k/705.6 k/1411.2 k Hz at the same time.

It can be understood that in the above embodiments, the integrator-comb filter 10, each half-band filter, and the multi-phase filter 22 are all FIR filters, and each can be implemented with different orders, and can be set according to different performance requirements.

This application further provides an electronic apparatus, including the audio rate conversion system as described above. For the detailed structure of the audio rate conversion system, please refer to the above-mentioned embodiments, which will not be repeated here. It is understandable that since the above-mentioned audio rate conversion system is included in the electronic apparatus of this application, the embodiments of the electronic apparatus of this application includes all the technical solutions of the above-mentioned audio rate conversion system, and the achieved technical effects are also the same, which will not be repeated here.

It can be understood that the electronic apparatus can be a mobile phone, a computer, a smart bracelet or other electronic devices with audio playing function.

The above are only optional embodiments of this application, and thus does not limit the scope of this application, and the equivalent structural transformation made by the content of the specification and the drawings of this application, or directly/indirectly applied to other related technical fields are all included in the scope of this application.

What is claimed is:

1. An audio rate conversion system, comprising an integrator-comb filter, a multi-rate filter and a first half-band filter, an input of the integrator-comb filter being accessed with digital audio data, an output of the integrator-comb filter being sequentially connected to the multi-rate filter and the first half-band filter; wherein,
the integrator-comb filter is configured to reduce a rate of the digital audio data according to a preset decimation rate;
the multi-rate filter is configured to convert a rate of digital audio data output by the integrator-comb filter into a rate of digital audio data corresponding to an accessed control signal according to the control signal; and
the first half-band filter is configured to reduce a rate of digital audio data output by the multi-rate filter.

2. The audio rate conversion system of claim 1, wherein the preset decimation rate of the integrator-comb filter is 8/16/32/64/128/256, and the integrator-comb filter is configured to reduce a rate of digital audio data with a clock frequency of 12M Hz to 1500000/750000/375000/187500/93750/46875 Hz in sequence corresponding to the preset decimation rate.

3. The audio rate conversion system of claim 1, wherein the preset decimation rate of the integrator-comb filter is 8/16/32/64/128/256, and the integrator-comb filter is configured to reduce a rate of digital audio data with a clock frequency of 8 MHz to 1000000/500000/250000/125000/62500/31250 Hz in sequence corresponding to the preset decimation rate.

4. The audio rate conversion system of claim 2, wherein, the multi-rate filter comprises a first multi-rate filter supporting 48 k/96 k/192 k/384 k/768 k/1536 k Hz rate conversion, a second multi-rate filter supporting 32 k/64 k/128 k/256 k/512 k/1024 k Hz rate conversion and a third multi-rate filter supporting 44.1 k/88.2 k/176.4 k/352.8 k/705.6 k/1411.2 k Hz rate conversion, inputs of the first multi-rate filter, the second multi-rate filter and the third multi-rate filter are respectively connected to the integrator-comb filter, and outputs of the first multi-rate filter, the second multi-rate filter and the third multi-rate filter are respectively connected to the first half-band filter.

5. The audio rate conversion system of claim 4, wherein, the first multi-rate filter is configured to process digital audio data with a rate of 46875/93750/187500/375000/750000/1500000 Hz output by the integrator-comb filter to audio data with a rate of 48 k/96 k/192 k/384 k/768 k/1536 k Hz by sequentially multiplying 8, dividing 5, multiplying 8, dividing 5, multiplying 2 and dividing 5.

6. The audio rate conversion system of claim 4, wherein, the second multi-rate filter is configured to process digital audio data with a rate of 31250/62500/125000/250000/500000/1000000 Hz output by the integrator-comb filter to audio data with a rate of 32 k/64 k/128 k/256 k/512 k/1024 k Hz by sequentially multiplying 8, dividing 5, multiplying 8, dividing 5, multiplying 2 and dividing 5.

7. The audio rate conversion system of claim 4, wherein, the third multi-rate filter is configured to process digital audio data with a rate of 46875/93750/187500/375000/750000/1500000 Hz output by the integrator-comb filter to audio data with a rate of 44.1 k/88.2 k/176.4 k/352.8 k/705.6 k/1411.2 k Hz by sequentially multiplying 16 and dividing 17.

8. The audio rate conversion system of claim 1, wherein the first half-band filter is one of two first half-band filters, and the two first half-band filters are sequentially connected to an output of the multi-rate filter.

9. The audio rate conversion system of claim 1, further comprising a second half-band filter arranged in series between the integrator-comb filter and the multi-rate filter.

10. The audio rate conversion system of claim 1, further comprising an analog digital converter, wherein an output of the analog digital converter is connected to the input of the integrator-comb filter, and the analog digital converter is configured to convert received analog audio data into the digital audio data and then output the digital audio data to the integrator-comb filter.

11. An electronic apparatus comprising an audio rate conversion system, wherein the audio rate conversion system comprises an integrator-comb filter, a multi-rate filter and a first half-band filter, an input of the integrator-comb filter being accessed with digital audio data, an output of the integrator-comb filter being sequentially connected to the multi-rate filter and the first half-band filter; wherein,
the integrator-comb filter is configured to reduce a rate of the digital audio data according to a preset decimation rate;
the multi-rate filter is configured to convert a rate of digital audio data output by the integrator-comb filter into a rate of digital audio data corresponding to an accessed control signal according to the control signal; and
the first half-band filter is configured to reduce a rate of digital audio data output by the multi-rate filter.

12. The electronic apparatus of claim 11, wherein the preset decimation rate of the integrator-comb filter is 8/16/32/64/128/256, and the integrator-comb filter is configured to reduce a rate of digital audio data with a clock frequency of 12M Hz to 1500000/750000/375000/187500/93750/46875 Hz in sequence corresponding to the preset decimation rate.

13. The electronic apparatus of claim 11, wherein the preset decimation rate of the integrator-comb filter is 8/16/32/64/128/256, and the integrator-comb filter is configured to reduce a rate of digital audio data with a clock frequency of 8 MHz to 1000000/500000/250000/125000/62500/31250 Hz in sequence corresponding to the preset decimation rate.

14. The electronic apparatus of claim 12, wherein, the multi-rate filter comprises a first multi-rate filter supporting 48 k/96 k/192 k/384 k/768 k/1536 k Hz rate conversion, a second multi-rate filter supporting 32 k/64 k/128 k/256 k/512 k/1024 k Hz rate conversion and a third multi-rate filter supporting 44.1 k/88.2 k/176.4 k/352.8 k/705.6 k/1411.2 k Hz rate conversion, inputs of the first multi-rate filter, the second multi-rate filter and the third multi-rate filter are respectively connected to the integrator-comb filter, and outputs of the first multi-rate filter, the second multi-rate filter and the third multi-rate filter are respectively connected to the first half-band filter.

15. The electronic apparatus of claim 14, wherein, the first multi-rate filter is configured to process digital audio data with a rate of 46875/93750/187500/375000/750000/1500000 Hz output by the integrator-comb filter to audio data with a rate of 48 k/96 k/192 k/384 k/768 k/1536 k Hz by sequentially multiplying 8, dividing 5, multiplying 8, dividing 5, multiplying 2 and dividing 5.

16. The electronic apparatus of claim 14, wherein, the second multi-rate filter is configured to process digital audio data with a rate of 31250/62500/125000/250000/500000/1000000 Hz output by the integrator-comb filter to audio data with a rate of 32 k/64 k/128 k/256 k/512 k/1024 k Hz by sequentially multiplying 8, dividing 5, multiplying 8, dividing 5, multiplying 2 and dividing 5.

17. The electronic apparatus of claim 14, wherein, the third multi-rate filter is configured to process digital audio data with a rate of 46875/93750/187500/375000/750000/1500000 Hz output by the integrator-comb filter to audio data with a rate of 44.1 k/88.2 k/176.4 k/352.8 k/705.6 k/1411.2 k Hz by sequentially multiplying 16 and dividing 17.

18. The electronic apparatus of claim 11, wherein the first half-band filter is one of two first half-band filters, and the two first half-band filters are sequentially connected to an output of the multi-rate filter.

19. The electronic apparatus of claim 11, wherein the audio rate conversion system further comprises a second half-band filter arranged in series between the integrator-comb filter and the multi-rate filter.

20. The electronic apparatus of claim 11, wherein the audio rate conversion system further comprises an analog digital converter, wherein an output of the analog digital converter is connected to the input of the integrator-comb filter, and the analog digital converter is configured to convert received analog audio data into the digital audio data and then output the digital audio data to the integrator-comb filter.
